(19) United States
(12) Patent Application Publication
(10) Pub. No.: US 2024/0421025 A1
(43) Pub. Date: Dec. 19, 2024

(54) ENHANCED I/O SEMICONDUCTOR CHIP PACKAGE AND COOLING ASSEMBLY HAVING SIDE I/OS

(71) Applicant: Intel Corporation, Santa Clara, CA (US)

(72) Inventors: Lianchang DU, Kunshan (CN); Jeffory L. SMALLEY, Olympia, WA (US); Srikant NEKKANTY, Chandler, AZ (US); Eric W. BUDDRIUS, Hillsboro, OR (US); Yi ZENG, Shanghai (CN); Xinjun ZHANG, Shanghai (CN); Maoxin YIN, Shanghai (CN); Zhichao ZHANG, Chandler, AZ (US); Chen ZHANG, Shanghai (CN); Yuehong FAN, Shanghai (CN); Mingli ZHOU, Shanghai (CN); Guoliang YING, Shanghai (CN); Yinglei REN, Shanghai (CN); Chong J. ZHAO, West Linn, OR (US); Jun LU, Shanghai (CN); Kai WANG, Portland, OR (US); Timothy Glen HANNA, Tigard, OR (US); Vijaya K. BODDU, Pleasanton, CA (US); Mark A. SCHMISSEUR, Phoenix, AZ (US); Lijuan FENG, Shanghai (CN)

(21) Appl. No.: 18/290,289

(22) PCT Filed: Dec. 16, 2021
(86) PCT No.: PCT/CN2021/138753

§ 371 Date: Nov. 10, 2023

(51) Int. Cl. H01L 23/367; H01L 23/538; H01L 25/065; H01R 13/627

(52) U.S. Cl. CPC H01L 23/3675; H01L 23/538; H01L 25/0655; H01R 13/6271

(57) ABSTRACT

A semiconductor chip package is described. The semiconductor chip package has a substrate. The substrate has side I/Os on the additional surface area of the substrate. The side I/Os are coupled to I/Os of a semiconductor chip within the semiconductor chip package. A cooling assembly has also been described. The cooling assembly has a passageway to guide a cable to connect to a semiconductor chip's side I/Os that are located between a base of a cooling mass and an electronic circuit board that is between a bolster plate and a back plate and that is coupled to second I/Os of the semiconductor chip through a socket that the semiconductor chip's package is plugged into.

### BACKGROUND

System design engineers face challenges, especially with respect to high performance data center computing, as both computers and networks continue to pack higher and higher levels of performance into smaller and smaller packages. Creative packaging solutions are therefore being designed to keep pace with the thermal and input/output (I/O) requirements of such aggressively designed systems.

### DRAWINGS

FIGS. 1a, 1b, 1c, 1d, 1e, 1f, 1g, 1h, 1i, 1j, 1k, and 1l pertain to a prior art cooling assembly;

FIG. 2 shows a high level view of an improved cooling assembly;

FIGS. 3a, 3b, 3c, 3d, 3e, 3f, 3g, 3h, 3i, 3j, 3k, 31, 3m, 3n, 30, 3p, 3q, 3r, 3s, 3t, 3u, 3v and 3w pertain to a first embodiment of an improved cooling assembly;

FIGS. 4a, 4b, 4c, 4d, 4e, 4f, 4g, 4h, and 4i pertain to a second embodiment of an improved cooling assembly;

FIGS. 5a, 5b, 5c, and 5d pertain to a third embodiment of an improved cooling assembly;

FIG. 6 shows a liquid cooling system

FIG. 7 shows a system;

FIG. 8 shows a data center;

FIG. 9 shows a rack.

### DETAILED DESCRIPTION

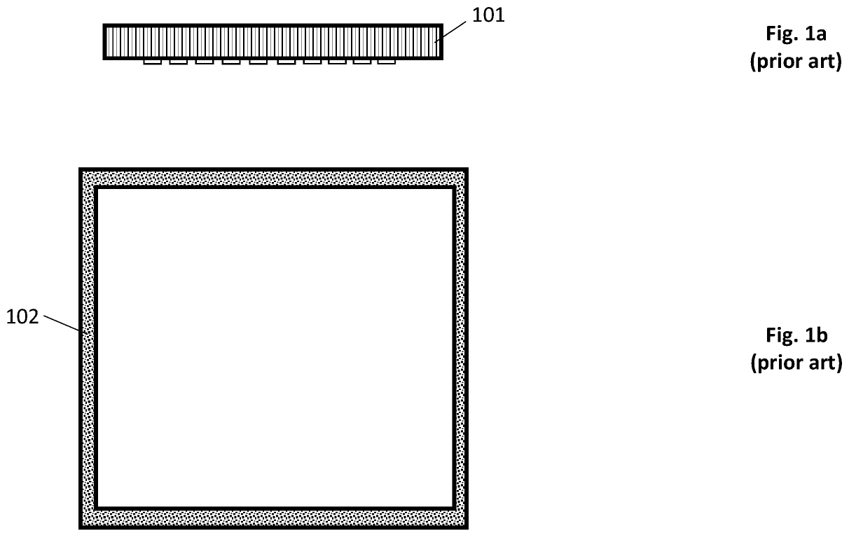

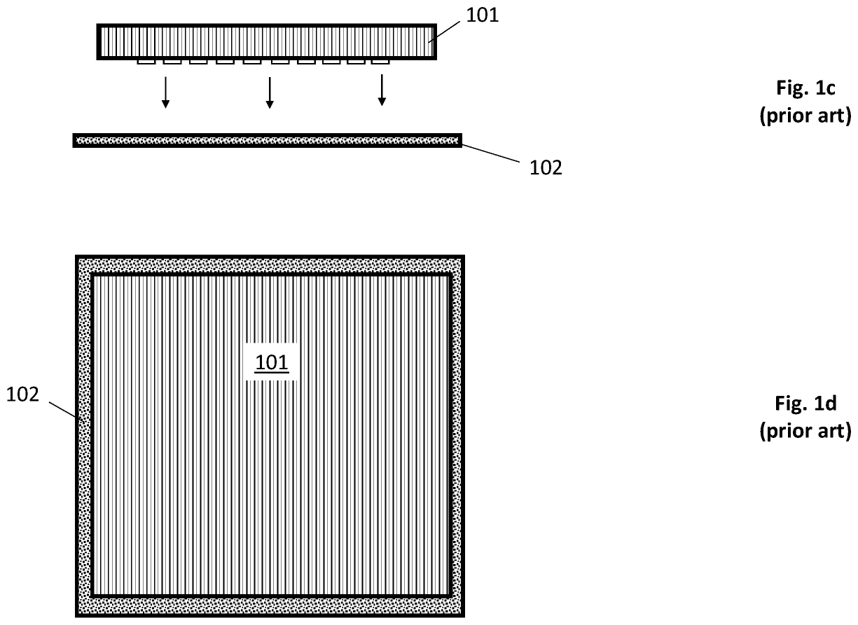

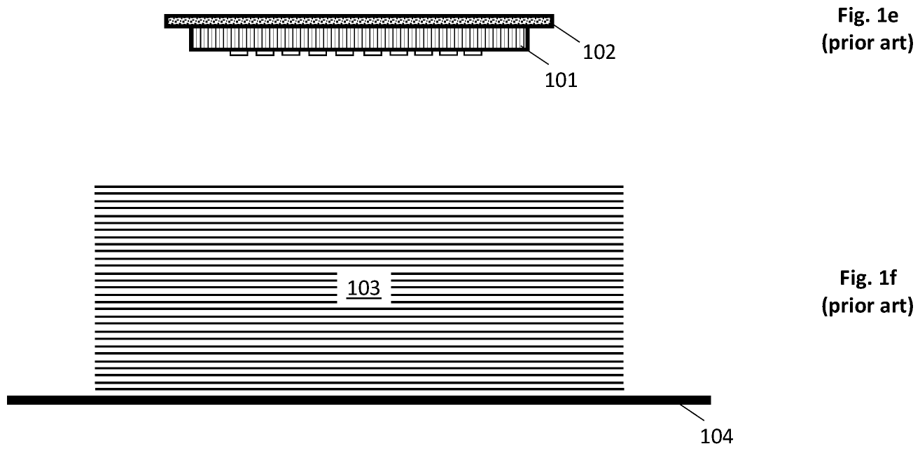

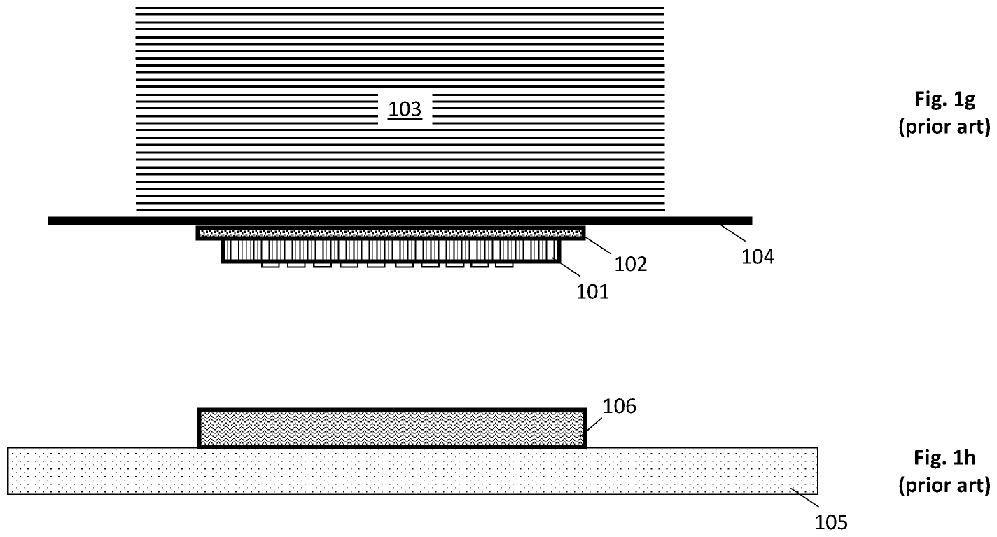

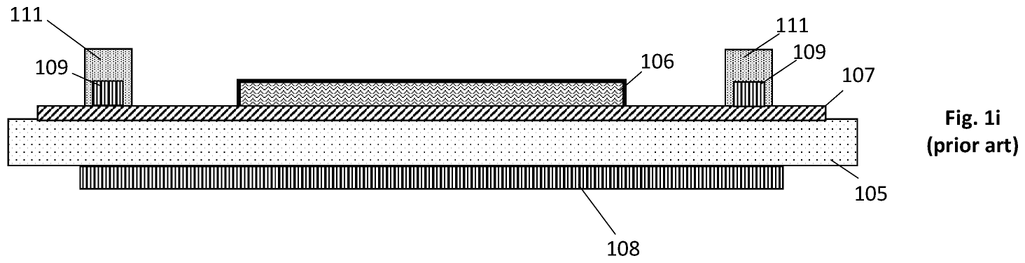

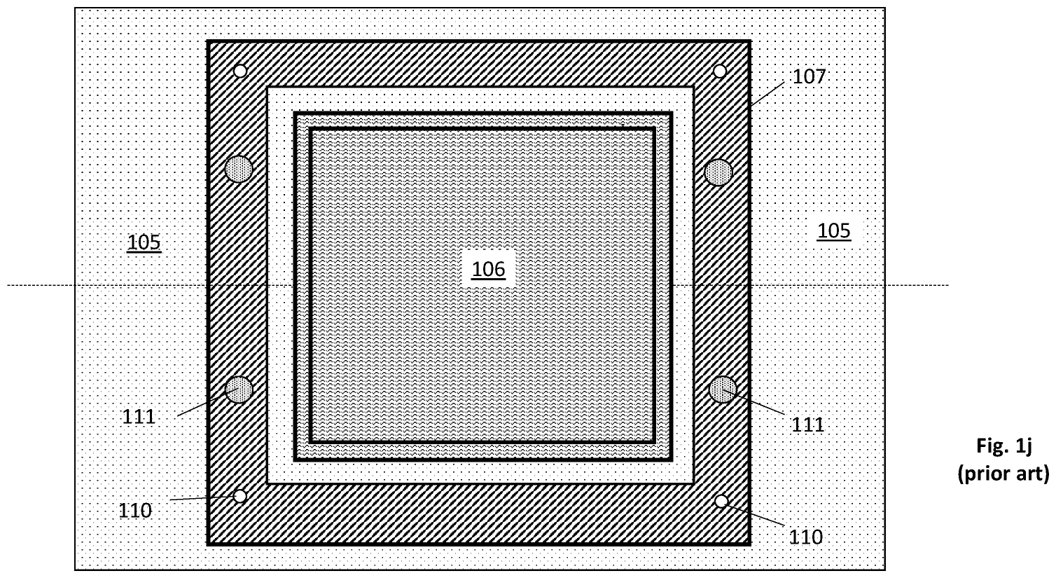

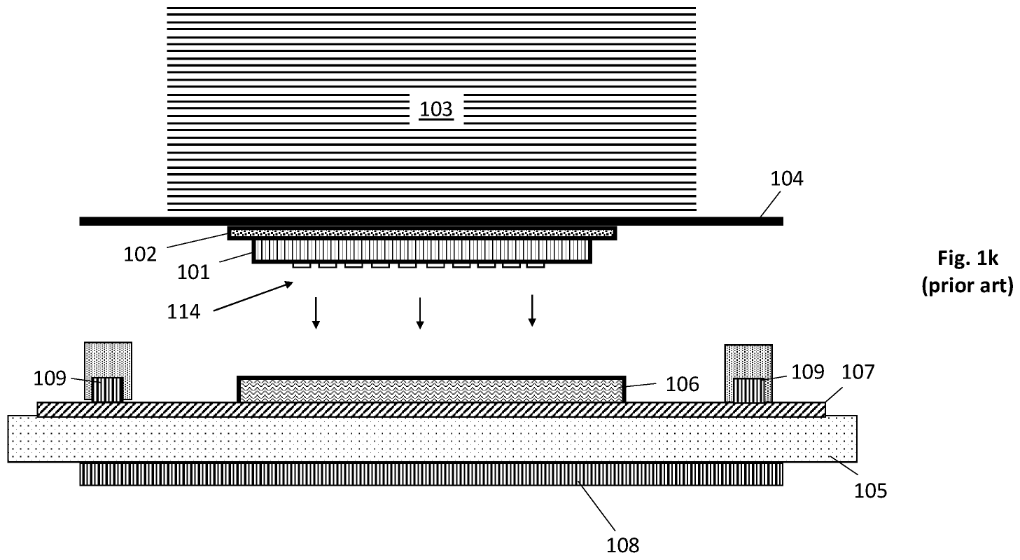

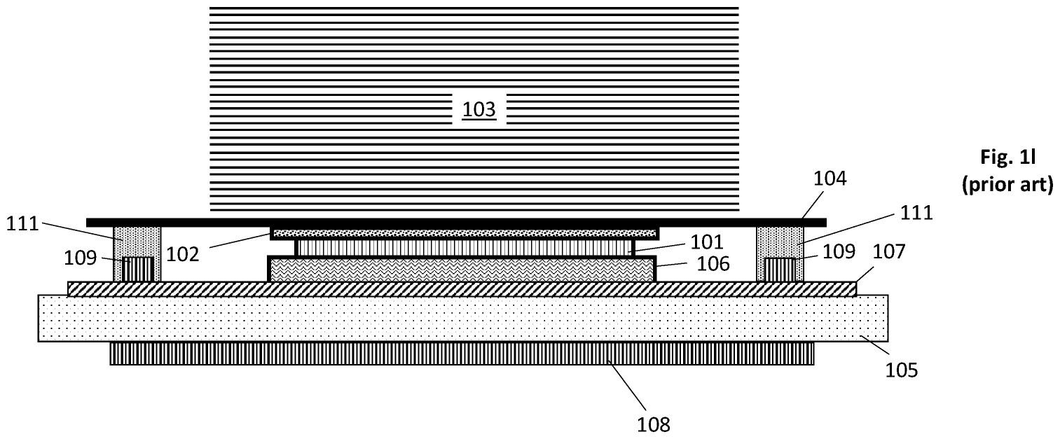

FIGS. 1a through 1l pertain to a heat sink assembly for a semiconductor chip package. FIG. 1a shows a side view of a semiconductor chip package 101. The semiconductor chip package 101 includes one or more semiconductor chips within the package 101. FIG. 1b shows a top down view of a semiconductor chip package carrier 102. FIG. 1c shows a side view of the semiconductor chip package 101 being placed within the open window of the carrier 102.

FIG. 1d shows a top down view of the chip package 101 within the carrier 102 while FIG. 1e shows a side view of the chip package 101 within the carrier 102. Here, as can be seen in FIGS. 1d and 1e, the carrier 102 acts as a kind of frame in which the chip package 101 is held (“carried”).

FIG. 1f shows a heat sink 103 with integrated base 104. After the chip package 101 has been inserted into the carrier 102, as observed in FIG. 1g, the carrier 102 is mounted to the underside of the heat sink base 104. Here, the heat sink base 104 and carrier 102 include mounting features (e.g., posts, through holes, threaded holes, screws, bolts, etc.), which are not shown in FIG. 1f for illustrative ease, that enable the carrier 102 to be rigidly mounted to the base 104 underside.

With the carrier 102 holding/carrying the chip package 101 in a precise location relative to the carrier 102 (due its frame like design), and with the carrier 102 being rigidly mounted to the base underside 104 in a precise location, the chip package is rigidly secured in a precise location on the base 104 underside.

FIG. 1h shows a printed circuit board 105 (also referred to as an electronic circuit board) and a chip package socket 106 that is mounted to the printed circuit board 105. The printed circuit board 105 is typically a multi-layer substrate having alternating dielectric and wiring layers. The wiring layers are patterned to form wires that run between various electronic components that are to be coupled to the electronic circuit board 105. The socket 106 includes inputs/outputs structures (I/Os) such as solder balls on its underside (not shown in FIG. 1h) that are coupled to corresponding I/Os (e.g., pads) on the printed circuit board 105. “I/Os” are wiring structures that direct electrical signals into a semiconductor chip (input) and/or direct electrical signals out of a semiconductor chip (output).

FIG. 1i shows a side view of the printed circuit board 105 and socket 106 after a bolster plate 107 and back plate 108 have been mounted to the printed circuit board 105. FIG. 1j shows a top down view of the same structure of FIG. 1i. As can be seen in FIG. 1i, the bolster plate 107 is a frame-like structure. The bolster plate 107 is positioned on the printed circuit board 105 such that the socket 106 is within the open window of the bolster plate 107. Referring to FIGS. 1i and 1j, the back plate 108 has studs 109 that are aligned

with holes 110 in the bolster plate 107. When the back plate 108 is mounted to the printed circuit board 105, the studs 109 pass through holes 110. The studs 109 are threaded and nuts (not shown) are tightened on the studs 109 to rigidly secure the bolster plate 107 to the back plate 108 with the printed circuit board 105 in between.

Then, referring to FIGS. 1k and 1l, the heat sink 103 with mounted carrier 102 and chip package 101 is mounted to the socket 106 and bolster plate 107. Here, the socket 106 has exposed I/Os (e.g., a land grid array (LGA)) facing the underside of the chip package 101. Likewise, the underside of the chip package 114 has corresponding I/Os (e.g., an array of pads). When the chip package is inserted into the socket 106, the package I/Os align and make contact to their corresponding socket I/Os forming electrical wire coupling between the socket 106 and chip package 101, which, in turn, forms electrical wire coupling between the chip package 101 and the printed circuit board 105 (the aforementioned I/Os on the underside of the socket 106 become electrical extensions of the I/Os on the underside 114 of the chip package 101).

The bolster plate 107 further includes mounting posts 111 that are aligned with holes in the heat sink base 104. The heat sink base 104 is rigidly mounted to posts 111. The mounting of the heat sink base 104 to the mounting posts 111 typically includes some spring loaded hardware that applies a loading force between the heat sink base 104 and bolster plate 107 (e.g., a spring that is increasingly extended as the heat sink base 104 is more rigidly secured to the posts 111). With the heat sink base 104 being rigidly secured to the posts 111, and with the bolster plate 107 being rigidly secured to the back plate 108 with the printed circuit board 105 there between, the weight of the heat sink 103 is born more by the bolster plate 107 and back plate 108 than the printed circuit board 105, chip package 101 and socket 106.

A problem is that future generations of silicon chip manufacturing technology will drive higher performance semiconductor chips characterized by increased transistor packing densities and corresponding increased amounts of dissipated heat and increased number of I/Os. Unfortunately, the increased dissipated heat combined with the increased number of I/Os creates packaging challenges that are best met through increased loading forces applied to the overall assembly.

Specifically, increasing the number of I/Os associated with the chip package 101

and socket 106 increases the propensity for the chip package 101 to “pop out” of the socket 106, and/or, the connector 106 to “pop off” the printed circuit board 105. The propensity to “pop out” and “pop off” is particularly severe with LGAs which are spring-like and exert push-back.

A solution is to place the additional I/Os introduced by future generation chips somewhere other than the bottom side of the chip package 101.

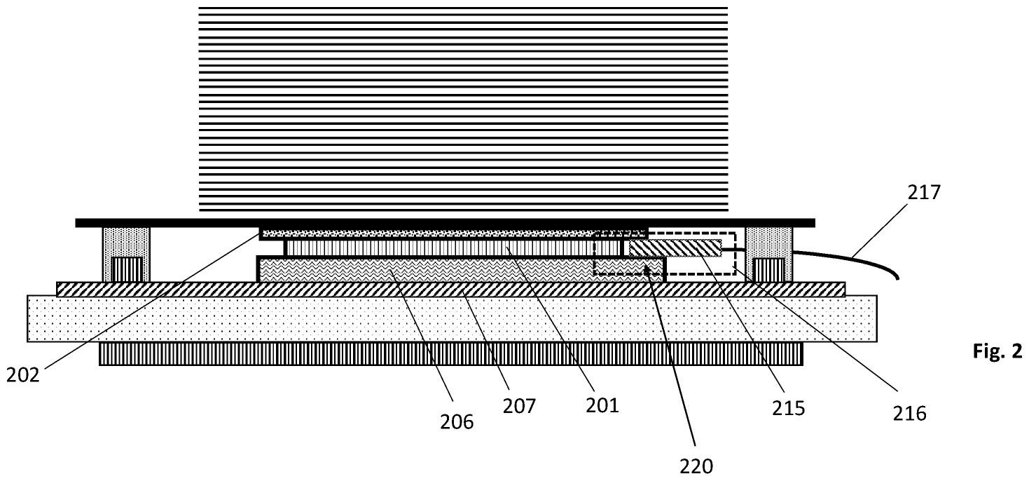

FIG. 2 shows an improved packaging approach where additional I/Os, e.g., associated with future generation higher density logic chips, are located near the side of the chip package 201 rather than the underside of the chip package 201.

Here, FIG. 2 depicts a cable 217 composed of multiple signal wires/lanes that terminate with a connector 215. The connector 215 mates with an I/O structure 220 (“side I/Os”) that is designed into a region 216 of the assembly that is near the side of the chip package 201. The cable 217 and its connector 215 are inserted into a passageway that is formed in the cooling assembly and runs from an outer edge of the cooling assembly to the side I/Os 220. The cable 217 and its connector 215 are pushed through the passageway until the connector 215 is aligned with the side I/Os 220. The connector 215 then mates with the side I/Os 220.

With this approach, over multiple generations of future semiconductor chip manufacturing technology, the I/O count on the underside of the chip package 201 can remain approximately constant while the I/O count near the sides of the package 201 are expanded in response to the increasing I/O count per chip. So doing limits the aforementioned “pop out” and “pop off” effects, while, at the same time, accommodates the additional I/Os presented by each next generation semiconductor chip.

As will be demonstrated in the discussions that follow, various different “side I/O” structures 220 can exist. Here, the relative dimensions of the bolster plate 207, chip carrier 202, socket 206 and/or chip package 201 can influence the precise mechanical features that are integrated into the region 216 to enable connection to the side I/Os 220.

Generally, however, region 216 contains side I/Os 220 near the side of the chip package 201 and one or more passageways designed into the cooling assembly to guide one or more cable connectors 215 to the side I/Os 220 so that the cable connectors 215 can mate to them. Some embodiments are described immediately below.

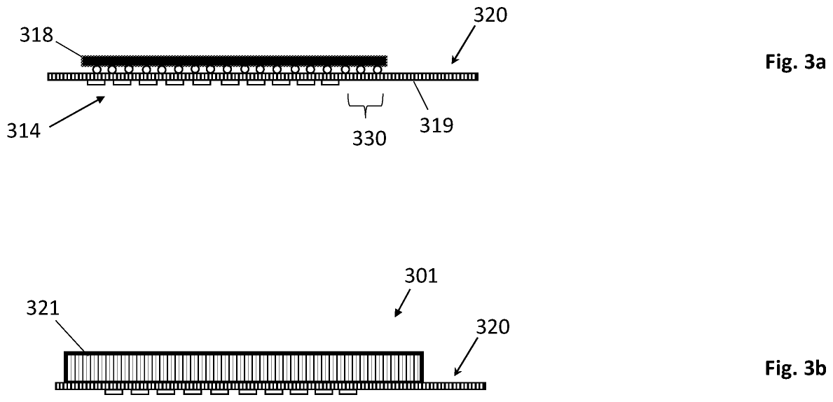

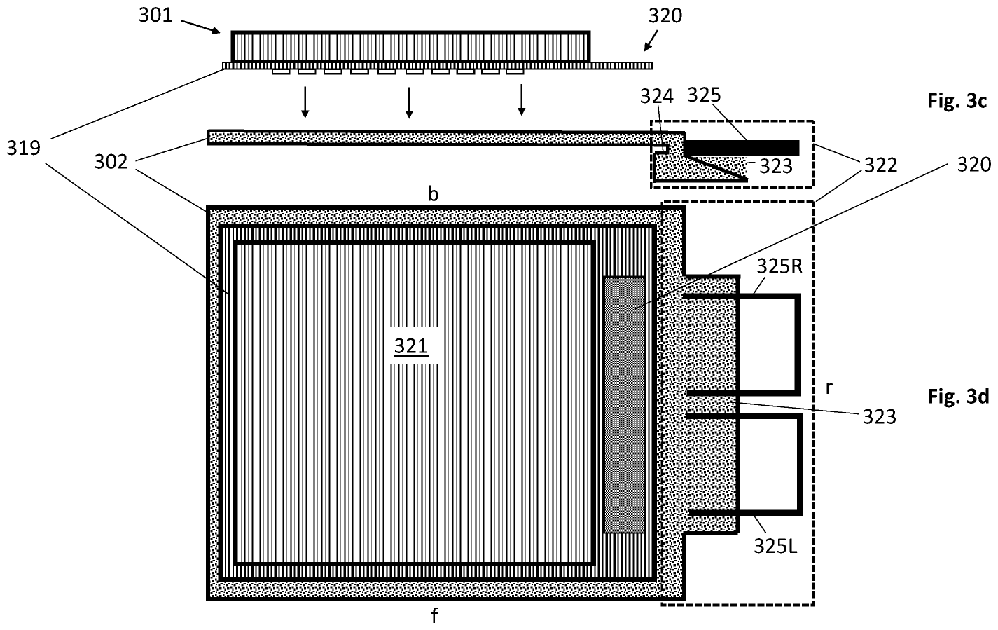

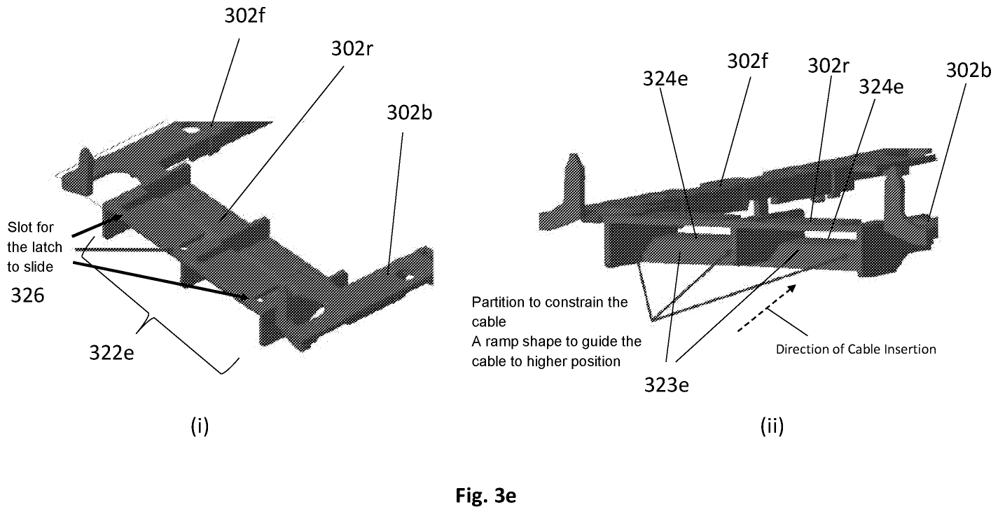

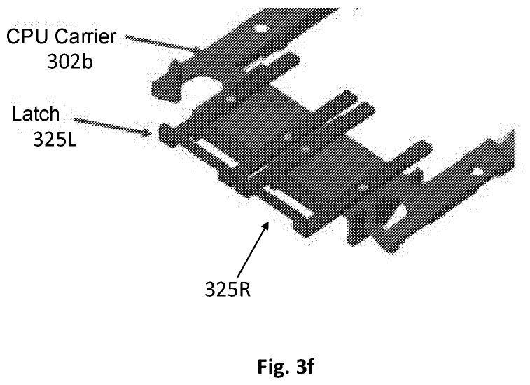

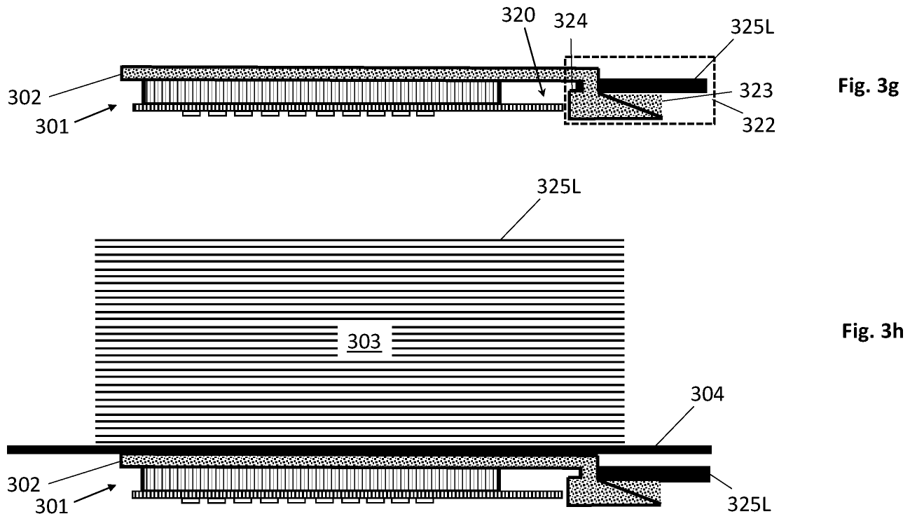

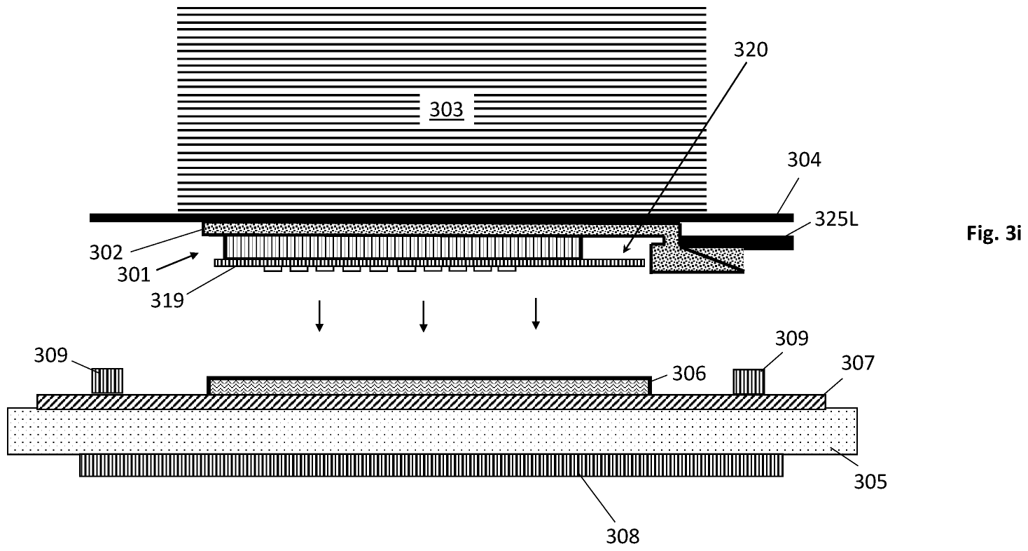

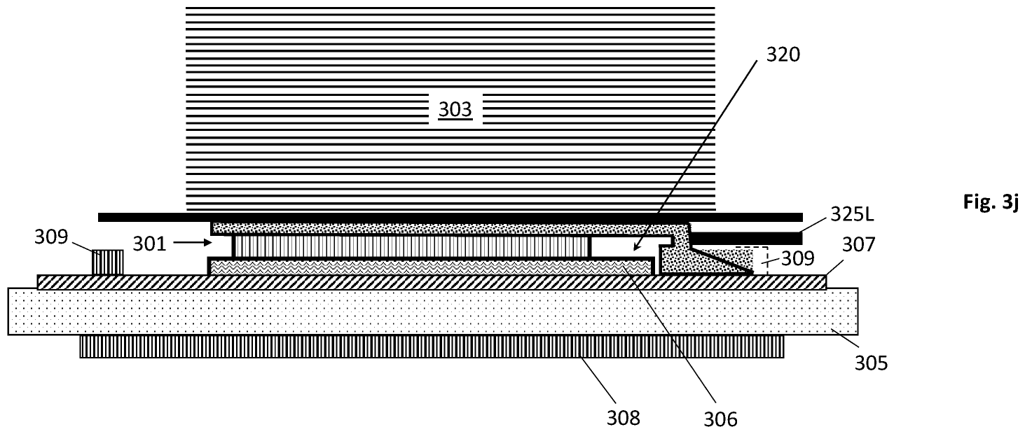

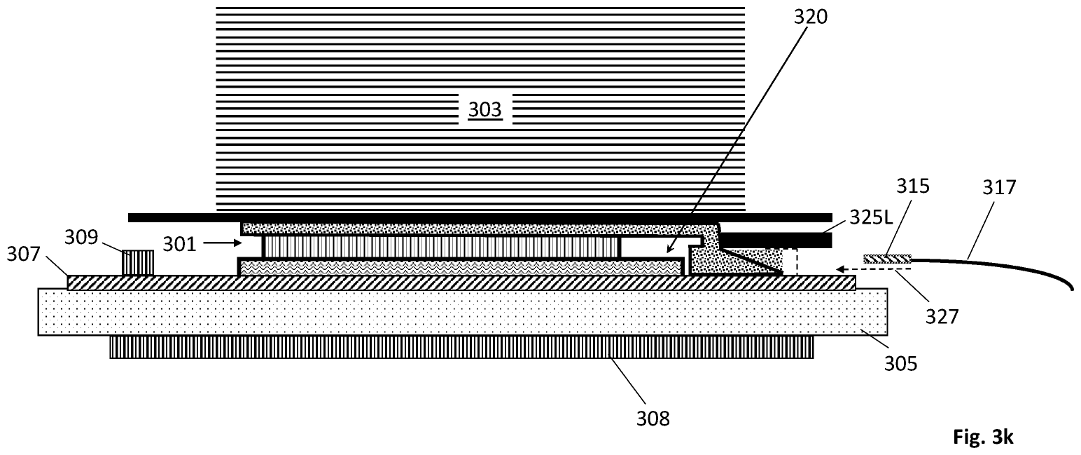

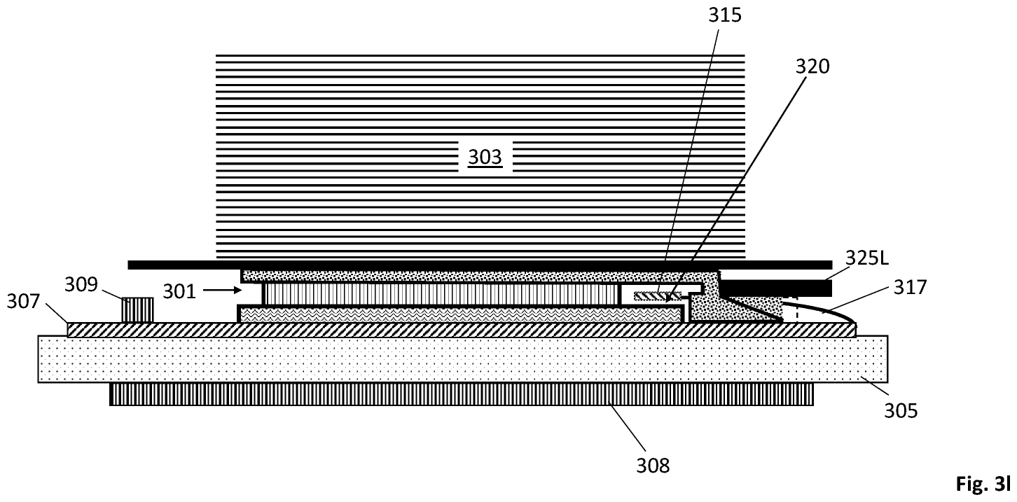

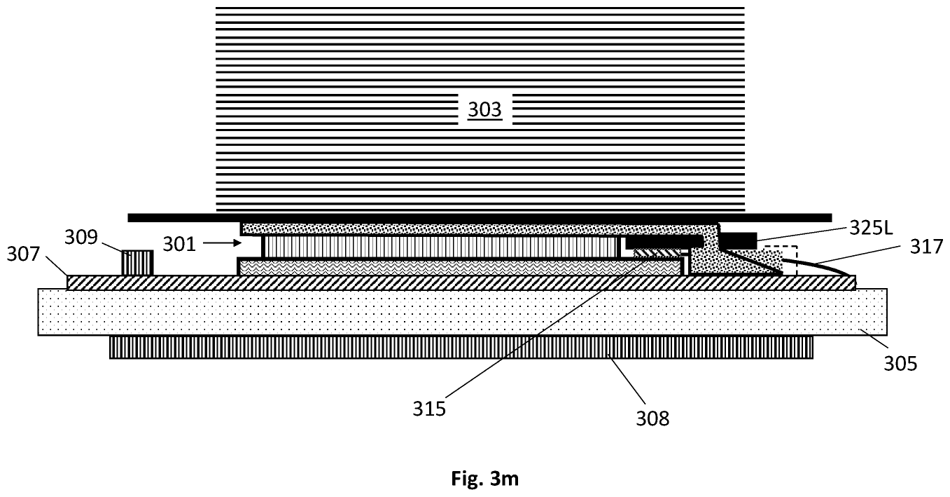

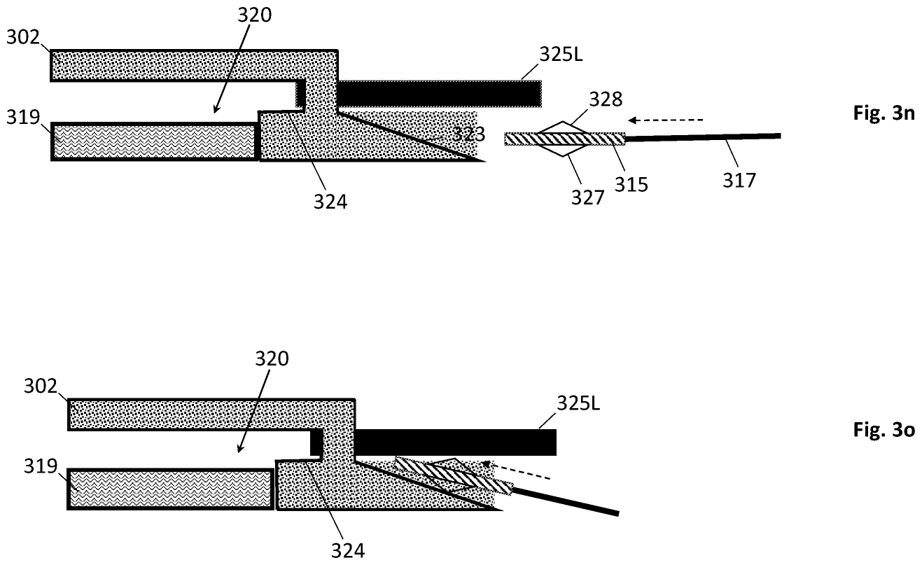

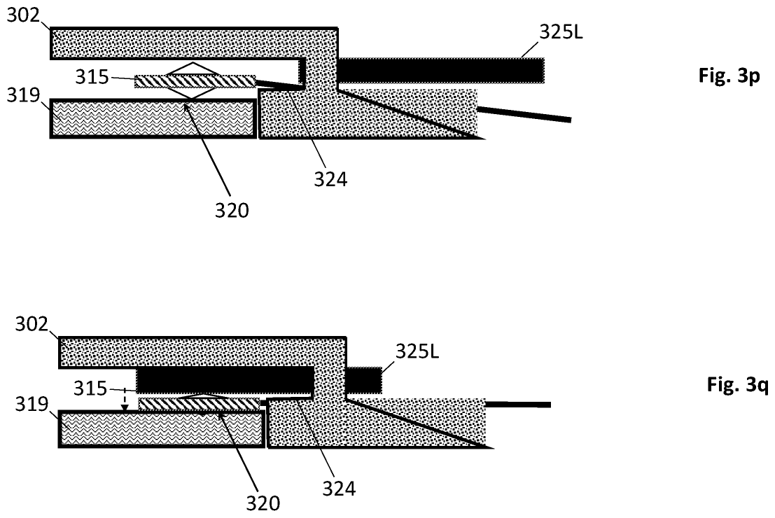

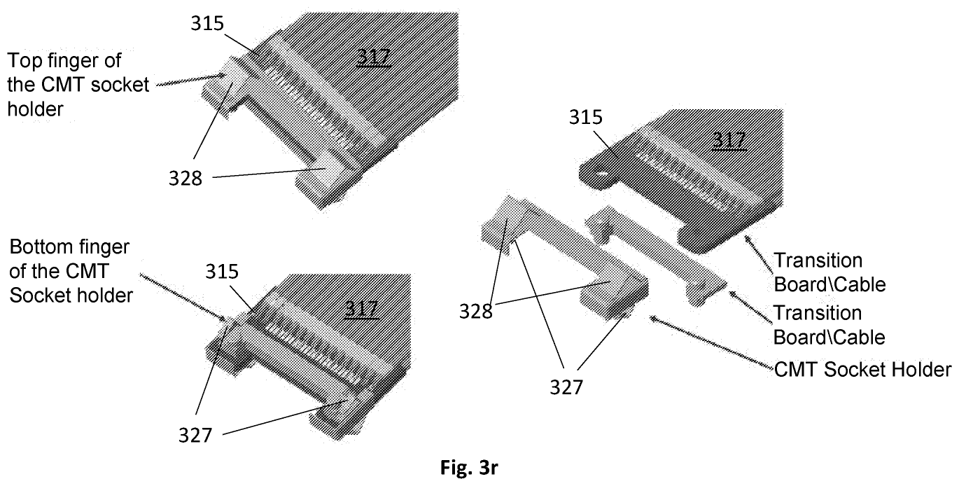

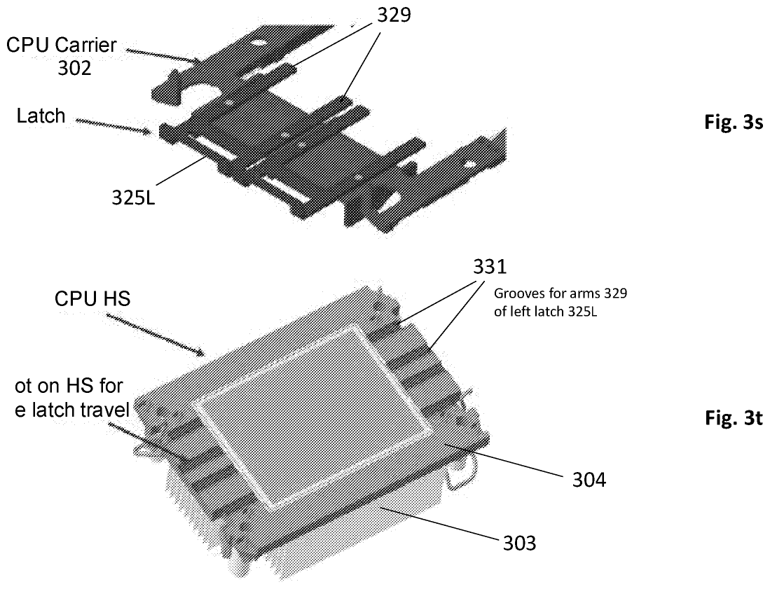

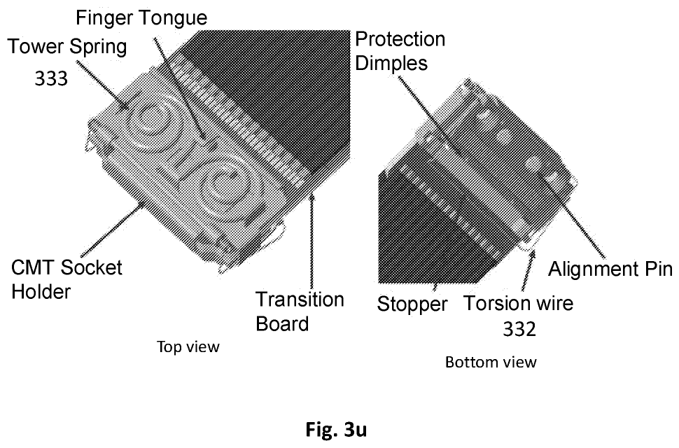

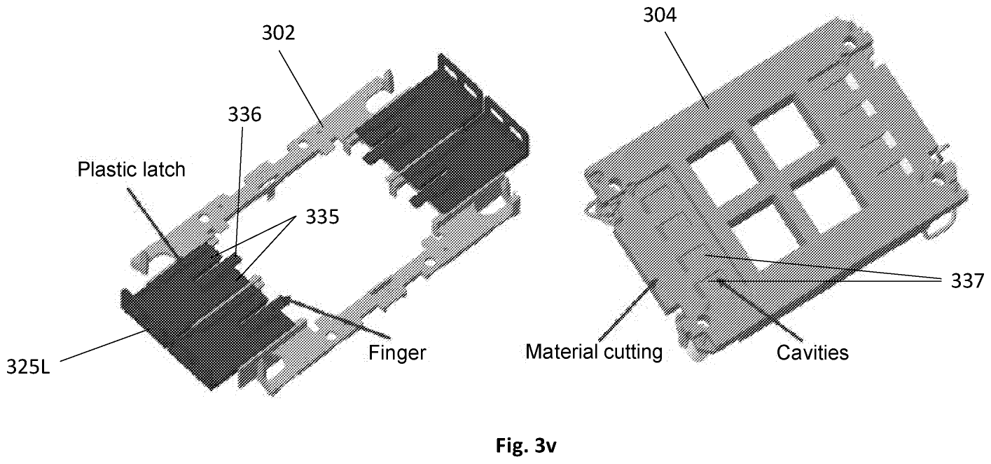

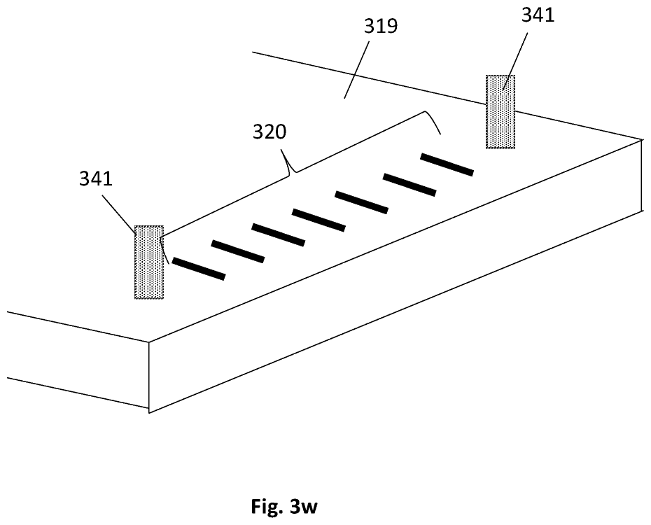

FIG. 3a through 3u pertain to a first approach in which the passageway(s) for guiding cable(s) to the I/Os are mechanically integrated into the chip carrier and the side I/Os are located on the chip package substrate.

FIG. 3a shows a semiconductor chip 318 mounted to a chip package substrate 319. As observed in FIG. 3a, the chip I/Os are implemented as conductive balls/bumps on the underside of the chip 318 which are soldered to corresponding pads on the chip package substrate 319. Notably, the chip 318 can be a next generation chip 318 having more I/Os than the number of I/Os on the underside 314 of the package substrate 319. For example, the I/Os associated with region 330 on the underside of the chip 318 may correspond to additional I/Os presented by a next generation chip 318 that exceed the number of I/Os on the underside of the package substrate 319.

Here, the package substrate 319 is a printed circuit board that includes internal wiring structures to couple the chip's I/Os to the package substrate's I/Os. Additionally, the package substrate 319 includes internal wiring structures to couple the additional chip I/Os to side I/Os 320. In the embodiment of FIG. 3a, the side I/Os 320 are conductive pads or lands formed on the upper surface of the package substrate 319. In other embodiments, one or more sockets are mounted to such pads/lands on the package substrate (and the aforementioned cable connector plugs into these socket(s)). Because the side I/Os 320 are implemented as pads/lands on the package substrate in the present embodiment, the side I/Os are not visible in the side view of FIG. 3a.

As will become more clear in the following discussion, and as described briefly above with respect to FIG. 2, an external cable with connector will mate with the side I/Os 320 to form additional electronic signal paths to/from the chip 318 from near the side of the chip 318.

FIG. 3b shows the completed chip package 301 after the chip 318 has been hermetically sealed by bonding an integrated heat spreader (IHS) 321 (also referred to as a package lid) to the package substrate 319. Notably, the chip package substrate and IHS of a traditional chip package have approximately the same size footprint (or cover approximately the same amount of surface area). By contrast, the substrate 319 of the chip package 321 of FIG. 3b is noticeably larger than the IHS in order to accommodate the side I/Os 320.

It is pertinent to point out that although only chip 318 is attached to the substrate 319, in other embodiments more than one chip can be attached to the substrate 319 and covered by a same HIS. Moreover, the chip package I/Os on the underside 314 of the substrate 319 are centered beneath the IHS as drawn in FIGS. 3a and 3b. In alternate embodiments, the chip package I/Os on the underside 314 of the package substrate 319 can be more evenly spread out on the underside of the (larger) substrate 319 (e.g., to more evenly spread out the loading force between the chip package 321 and the socket that chip package will be inserted into).

FIG. 3c depicts the chip package 321 being inserted into the chip carrier 302. Notably, the chip carrier 302 has special mechanical features within region 322. Such special mechanical features include a ramp feature 323, a raised floor feature 324 and a latch 325. As will be described in more detail further below, the ramp 323 and floor features 324 help guide a cable connector to the side I/Os 320. The latch 325 helps secure the cable connector to the side I/Os 320 after the cable connector is aligned with the side I/Os 320.

FIG. 3d shows a top down view of the chip package 321 after its insertion into the chip carrier 302. Here, notably, there are two latches 325L and 325R. As will be described in more detail further below, in the particular embodiment being described, the respective connectors of a pair of cables (“left” and “right”) will make contact with the side I/Os 320. As such, there are two latches 325L, 325R (one for each cable).

FIG. 3e shows a more detail view of a particular embodiment of the chip carrier 302 described above with respect to FIGS. 3c and 3d. Here, referring briefly back to FIG. 3d, note that the chip carrier has a front side (“f”), a back side (“b”) and a right side (“r”). The front side is toward the bottom of FIG. 3d, the back side is toward the top of FIG. 3d and the right side is toward the right of FIG. 3d. Thus, the chip carrier 302 can be viewed as a frame like structure having a front arm at the bottom of the carrier 302 as depicted, a back arm at the top of the carrier 302 as depicted, and a right arm having the cable alignment features 323, 324 and latches 325L and 325R. Notably, the field 320 where the side I/Os are located is visible in FIG. 3e. A more precise view would show a row or array of side I/O pads/lands in field 320.

Referring now to FIG. 3e, a pair of three dimensional drawings (i) and (ii) show an embodiment of the front arm 302f, the back arm 302b and the right arm 302r where a view of the right arm 302r is emphasized. Drawing (i) of FIG. 3e shows the general region 322e of the cable passageways. Drawing (ii) of FIG. 3e shows a left passageway and right passageway each having a ramp component 323e and raised floor component 324e (a partition in the middle of region 322e separates the two different passageways). As will be described in more detail below, a left cable with connector will be guided by the passageway on the left and a right cable with connector will be guided by a passageway on the right.

FIG. 3f shows the carrier 302 of FIG. 3e above with the aforementioned latches 325L, 325R. As will be described in more detail below, left latch 325L is pushed “in” toward the chip package to guide the left cable to the side I/Os and the right latch 325R is pushed “in” toward the chip package to guide the right cable to the side I/Os. Referring back to drawing (i) of FIG. 3e, grooves 316 are formed in the top surface of the right arm 302r of the chip carrier to guide the latches as they slide toward the side I/Os.

FIG. 3g shows a side view of the chip package 301 within the chip carrier 302. Note that in various embodiments, the latches 325L, 325R are integrated with the carrier 302 (by laying in the aforementioned grooves 326) when the chip package 301 is within the chip carrier 302. Being a side view, only left side latch 325L is visible in FIG. 3g.

FIG. 3h shows the structure after the chip carrier 302 has been mounted to the underside of the base 304 of the heat sink 303.

FIG. 3i shows the chip package 301 with carrier 302 and heat sink 303 being mounted to the bolster plate 307 (the bolster plate 307 has already been secured to the back plate 308). Here, the chip package 301 is aligned with its corresponding socket 306 on the printed circuit board 305. For illustrative ease, bolster plate posts 111 (or other mechanical features) used to respectively align and mount the heat sink 303 and chip package 301 to the bolster plate 307 and socket 306 are not depicted.

FIG. 3j shows the overall assembly after the heat sink 303 has been properly mounted to the bolster plate 307 and the chip package 301 has been properly inserted within the socket 306. For ease of viewing, rightmost back plate stud 309 has only been outlined so the guide features that emanate from the chip carrier 302 can be fully observed.

FIG. 3k shows a left side cable 317 with connector 315 being inserted 327 into a passageway that exists between the base of the heat sink and the bolster plate 307. Again, assuming the embodiment being described corresponds to an embodiment that supports two cables being placed in contact with the side I/Os 320 as discussed above with respect to FIGS. 3e and 3f, the observed cable 317 and connector 315 corresponds to a left side cable/connector and latch 325L corresponds to latch 325L of FIG. 3f. Notably, latch 325L is in a disengaged position (is pulled away from the chip package 301).

FIG. 3l depicts the assembly after the cable 317 has been pushed toward the chip package 301 a sufficient distance so that its connector 315 is aligned with the side I/Os 320. Latch 325L remains in the disengaged position.

FIG. 3m shows the assembly after the latch 325L has been pushed toward the chip package 301 to cause the cable connector 315 to be mated with and secured to the side I/Os 320.

FIGS. 3n, 3o, 3p, and 3q examine an embodiment of the connection of the cable connector 315 to the side I/Os 320 in more detail. FIGS. 3r, 3s, and 3t provide even further details of an embodiment of the mechanical design and are referred to during the discussion of the installation sequence of FIGS. 3n, 3o, 3p, and 3q.

FIG. 3n recreates the scenario of FIG. 3k in which the cable 317 and its connector 315 begins to be approach the passageway en route to the side I/Os 320. Here, compressible elbow springs 327, 328 reside on the top and bottom of the cable connector 315. The elbow springs 327, 328 can be formed, for example, with bent strips of metal (such as aluminum) or hard plastic that are thin enough to bend at the elbow but thick enough to provide spring-like resistance against such bending.

FIG. 3o depicts the cable 317 and connector 315 being pushed further along the passageway en route to the side I/Os 320 and riding up the ramp feature 323 of the passageway.

FIG. 3p shows the cable connector 315 after it has been pushed far enough to climb the ramp feature 323 of the passageway, run along the floor feature 324 of the passageway and align itself directly above the side I/Os 320. Here, the lower springs 327 resist compression which prevents the bottom of the cable connector 315 from rubbing against the ramp 323 and floor 324 features while the connector 315 is being inserted into the assembly. As described in more detail below, the cable connector's I/Os are located on the underside of the cable connector 315. As such, the lower springs 327 prevent damage to the cable connector's I/Os during insertion/removal of the cable connector 315 to/from the assembly.

In FIG. 3o, the connector 315 stops moving when the lower springs 327 engage in chock grooves (not shown) formed in the top surface of the package substrate near the side I/Os 320 (e.g., along side or next to the side I/Os). Here, the chock grooves are shaped like the bottom elbow springs 327 so that the bottom elbow springs 327 snugly fit into them thereby preventing further movement of the connector 315 toward the chip package.

In each of FIGS. 3n, 3o, and 3p, the latch 325L remains in the disengaged position. FIG. 3q shows the final position after the latch 325L has been pushed inward toward the chip package 301. Here, when the latch 325L is being pushed toward the chip package 301 for engagement, the arms 329 of the latch 325L are positioned to glide through the aforementioned grooves 326 in the right carrier arm 302r (FIG. 3e) and corresponding grooves 331 formed in the underside of the heat sink base 304.

Moreover, the lower and upper elbow springs 327, 328 are positioned toward the outer edges of the cable connector 315. The upper elbow springs 328 are aligned with the grooves 326, 331 that the latch arms 329 glide through. As such, when the latch 325L is pushed into the assembly for engagement, the latch arms 329 press into the upper elbow springs 328.

Referring to FIG. 3q, the upper elbow springs 328 compress in response to their being pressed upon by the latch arms 329 which forces the cable connector 315 to move downward. The downward motion of the cable connector 315 compresses the lower elbow connectors 327. The downward motion of the cable connector 315 causes the I/Os on the bottom surface of the cable connector 315 to make aligned contact with the side I/Os 320. As such, the pushing of the latch 325L forces electrical-mechanical contact between the cable connector 315 and the side I/Os 320, thereby electrically coupling the side I/Os with the wires in the cable 317.

Importantly, the resistance of the upper elbow springs 328 to their compression results in a compression mounted connection between the cable connector 315 and the side I/Os 320. That is, the recoil of the upper elbow springs 328 to their compression causes the bottom surfaces of the cable connector 315 to be firmly pressed against the upper surfaces of the side I/Os 320 thereby making good electrical and mechanical contact between the connector 315 and the side I/Os 320. Such up/down connection also preserves the mechanical integrity of the I/Os (minimal damage is imparted to them).

Additionally, any competing force caused by recoil of the lower elbow springs 327 to their compression (which acts to push the cable connector 315 away from the side I/Os 320) is greatly mitigated by designing the upper springs 328 to be wider than the lower springs 327. A wider metal strip width gives the upper springs 328 a larger spring constant than the lower springs 327 which results in greater force pushing down on the cable connector 315 by the upper springs 328 than force pushing upward on the cable connector 315 by the lower springs 327.

FIG. 3u shows an alternative cable connector design in which the lower elbow springs 327 are replaced by a torsion wire spring 332 and the upper elbow springs are replaced by coil springs 333. Note that the alternative cable connector can cause the latch arms and their grooves to be positioned further inward (closer to one another) than the latch arms 329 discussed above. Additionally, the groove formed in the chip package substrate near the side I/Os should be formed to fit the torsion wire (rather than a pair of elbow springs as described above).

FIG. 3v shows an alternative latch design in which the latch 325L includes a pair of outer, shorter tabs 335 and one longer middle tab 336. The shorter tabs 335 fit into depressions 337 formed on the underside of the heat sink base 304 and prevent further inward movement of the latch when the shorter tabs 335 press against the inner walls of the depressions 337. The middle tab 336 engages with an upper spring on the cable connector to cause the cable connector to move downward and connect to the side I/Os as described above. Note that the cable connector's upper spring should be positioned more toward the center of the cable connector to engage with the inner tab 336.

FIG. 3w shows a three dimensional perspective of the side of the chip package substrate 319 having the side I/Os 320. For ease of drawing the side of the chip package substrate 319 is designed to connect to a single cable connector rather than a pair of cable connectors. Additionally, the aforementioned grooves that the lower cable connector springs 327 slide into are not shown.

Notably, alignment pins 341 are observed emanating from the top surface of the chip package substrate 319. Alignment pins 341 are used to ensure the cable connector 315 is aligned with the side I/Os 320 when the cable connector 315 is lowered onto the side I/Os 320. Here, pins 341 slide into corresponding holes in the cable connector that reside near the edges of the cable connector 315 when the cable connector 315 is being pressed down onto the side I/Os 320 thereby aligning each one of the side I/Os 320 to its corresponding I/O on the cable connected.

The alignment pins 341, in various embodiments, are hardware structures that are mounted to the upper surface of the package substrate 319 (e.g., threaded posts that are inserted through holes in the substrate 319 and are tightened with screws on the underside of the substrate 319). In alternate embodiment the alignment pins are on the cable connector and the corresponding holes are formed in the chip package substrate 319.

In various embodiments, the cable connector's connection to the side I/Os 320 are secured simply by being pressed by the latch and springs as discussed above. In other embodiments, the cable connector's I/Os are soldered to the side I/Os 320, and/or, the cable connector 315 is screwed/bolted to hardware that is mounted on the package substrate 319 (like alignment pins 341).

Although the side I/Os are depicted in FIG. 3w as pads/lands, in other embodiments the side I/Os can be formed as pins that emanate from the chip package substrate (like alignment pins 341). In this case the cable connector I/Os are corresponding holes that the pins slide into. In another embodiment the pins emanate from the cable connector and the corresponding holes are formed on the chip package substrate. As mentioned above with respect to FIG. 2, the side I/Os can be housed in one or more sockets or other connectors that are mounted on the package substrate 319.

In still other embodiments, the cable connector I/Os and side I/Os are connected with liquid metal socket technology. As is known in the art, a liquid metal connection can be formed with a well and a liquid metal that is lowered into the well. In an embodiment, the wells are formed on the package substrate 319 as side I/Os 320 and the corresponding liquid metal I/Os that are inserted into the wells are formed on the cable connector.

The teachings mentioned above with respect to FIG. 3w are applicable not only to the embodiment of FIGS. 3a through 3v but also the following described embodiments or other side I/O implementation.

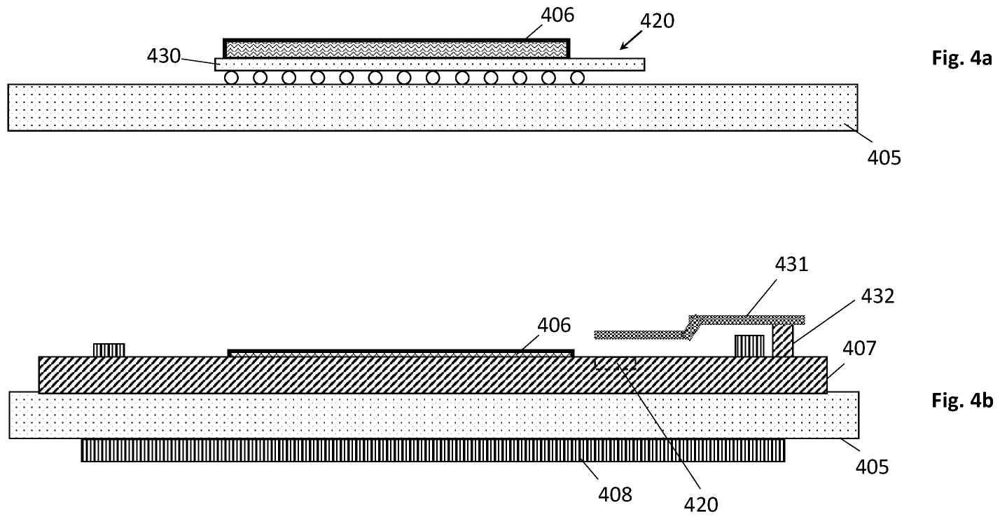

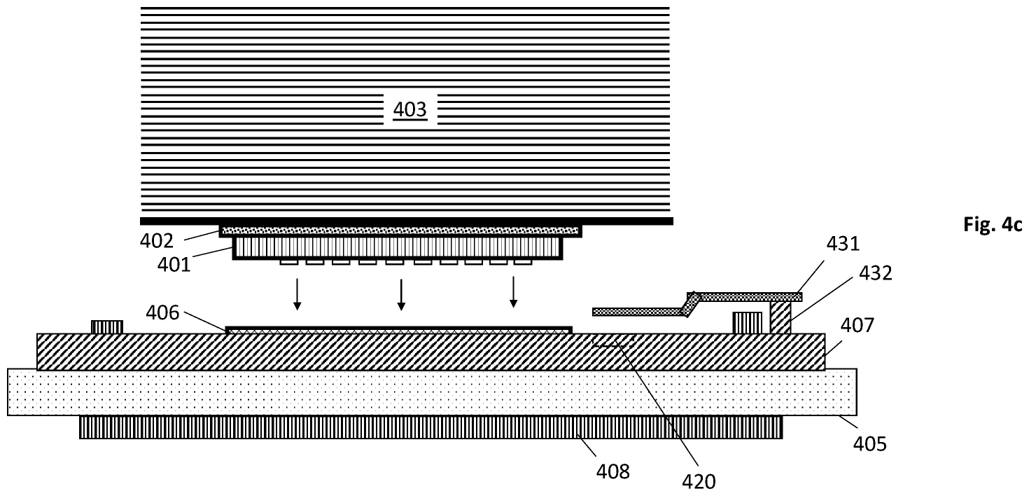

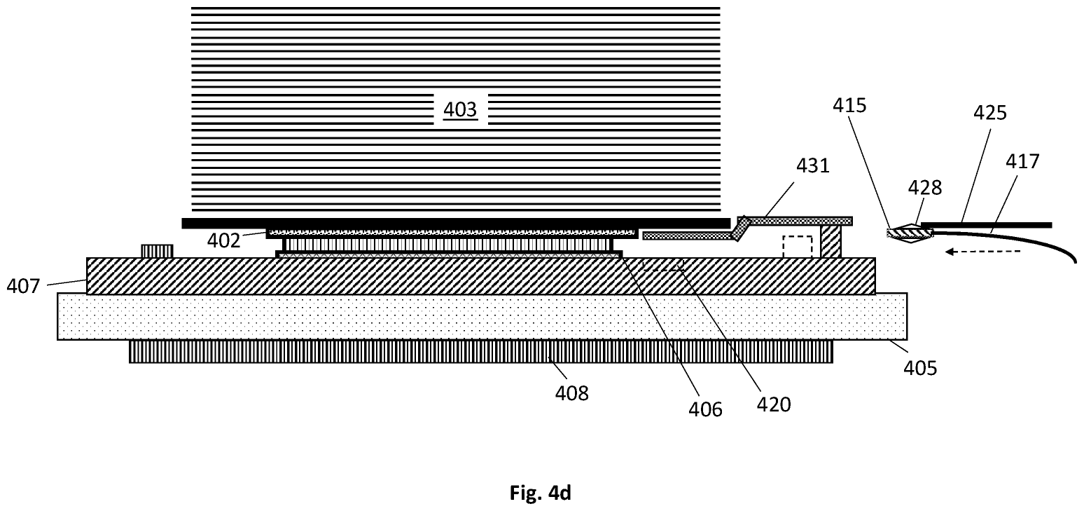

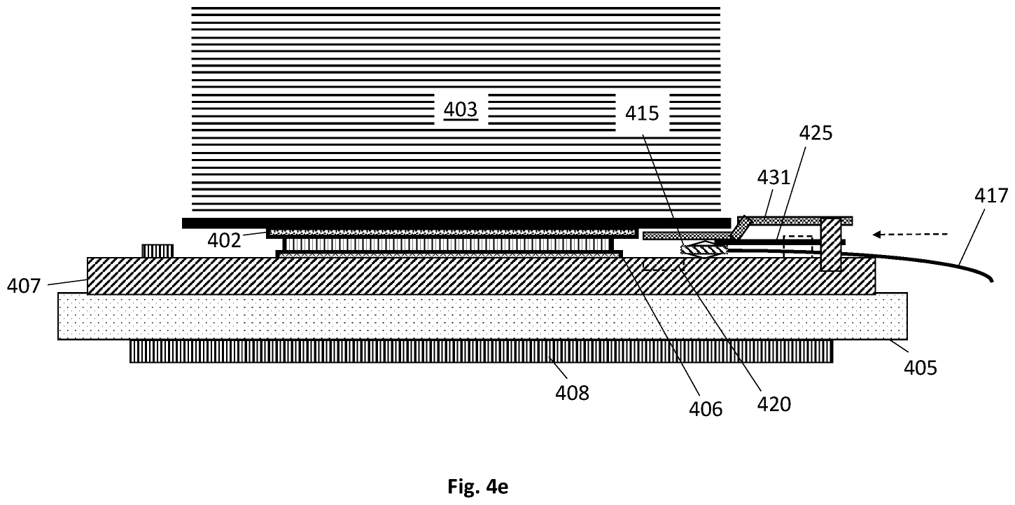

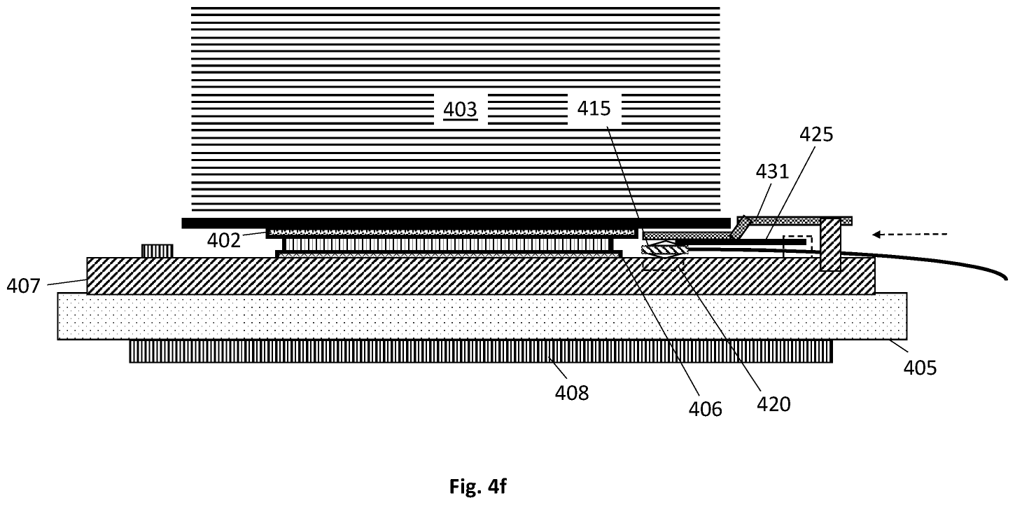

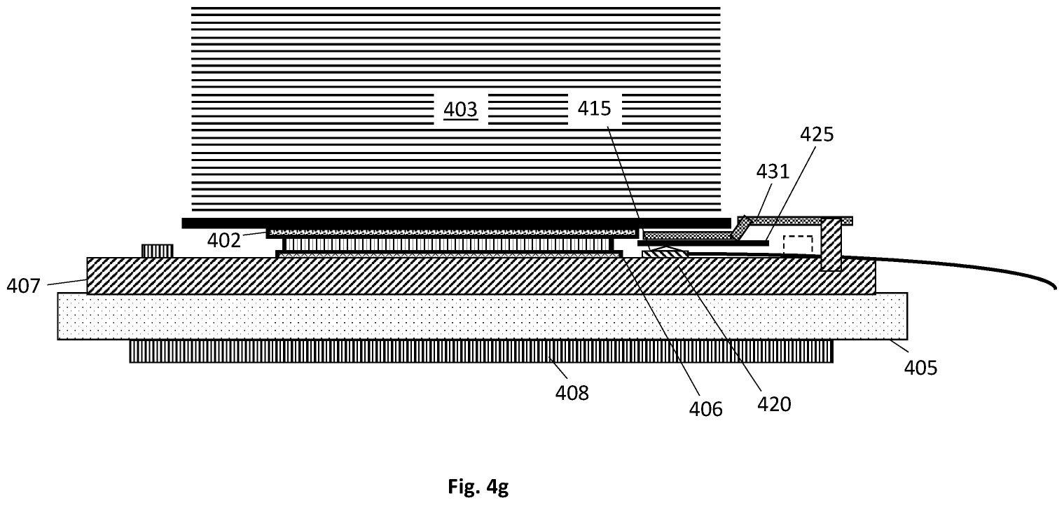

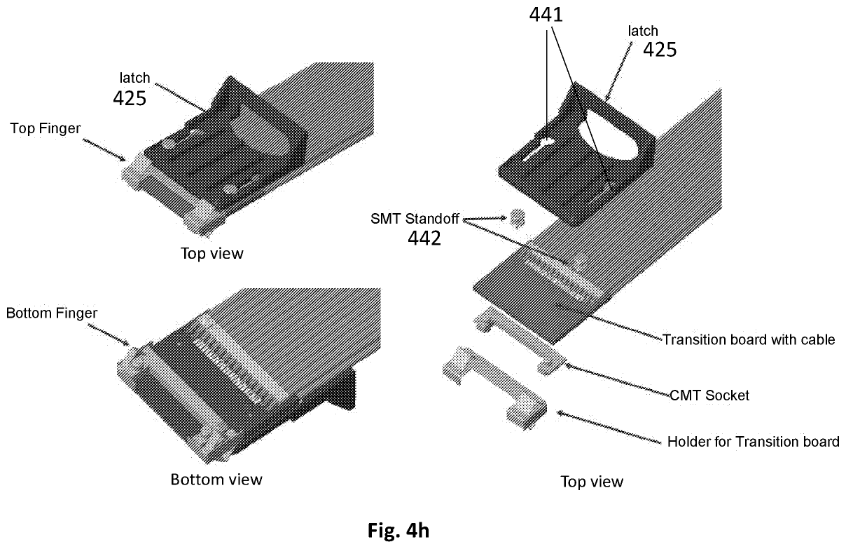

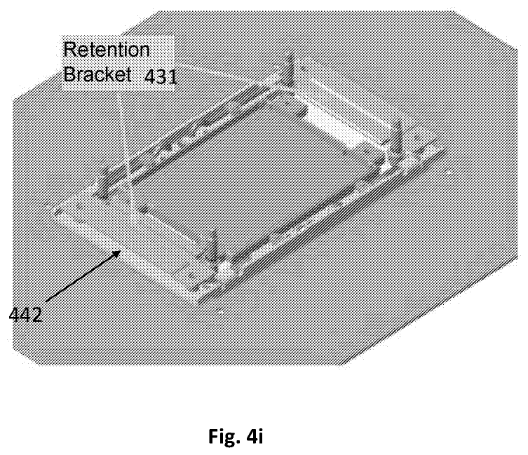

FIGS. 4a through 4i pertain to another mechanical design for connecting a cable and its connector to the side I/Os 420. As will be more clear below, a part of the passageway is formed with a retention bracket that is mounted to the bolster plate and a floor of the passageway is formed with the top surface of the bolster plate.

FIG. 4a shows an interposer printed circuit board 430 (“interposer”) having bottom side I/Os (balls, bumps, etc.) that are soldered to the top side of a printed circuit board 405. A silicon chip package socket 406 is soldered to the top side of the interposer 430. Side I/Os 420 exist on the top surface of the interposer 430.

FIG. 4b shows the structure after the bolster plate 407 and back plate 408 are tightly coupled together with the printed circuit board 405 in between. For ease of illustration, the top surface of the bolster plate 407 is approximately level with the top surface of the side I/Os 420 (other embodiments can have the top surface of the bolster plate 407 reside above or below the top surface of the side I/Os).

FIG. 4b also shows a post 432 emanating from the bolster plate 407 to which a retention bracket 431 is mounted. As will be described in more detail below, the retention bracket 431 helps guide the cable connector to the side I/Os 420.

A chip package and carrier are mounted to the underside of a heat sink base, e.g., as described above with respect to FIGS. 1a through 1g.

FIG. 4c shows the chip package 401 being plugged into the chip package socket 406. For illustrative ease, the hardware that mounts the heat sink 403 to the bolster plate 407 is not depicted (the manner described above with respect to post 111 and FIGS. 1i, 1j, 1k, and 1l can be used).

FIG. 4d shows a cable 417 and its connector 415 being entered into the space between the heat sink base 404 and the bolster plate 407. As with the previously described embodiment, the connector 415 includes lower elbow springs 427 and upper elbow springs 428. Notably, however, the latch 425 is mechanically integrated with the cable connector 415 rather than the chip carrier 402. As observed in FIG. 4d, when the cable is being inserted into the assembly, the latch 425 is in the disengaged position such that its leading face is “behind” the upper spring 428 (the upper spring 428 is between the side I/Os 420 and the face of the latch 425 that faces the side I/Os 420).

FIG. 4e shows the lower springs 427 of the connector 415 sliding along the top surface of the bolster plate 407 as the connector 415 is pushed closer to the side I/Os 420. Similar to the previously described embodiment, the lower springs 427 push the bottom of the connector 415 away from the surface of the bolster plate 407 thereby protecting the I/Os at the bottom of the connector 415. The retention bracket 431 is shaped to create a tunnel or other cavity that the cable connector 415 slides within toward the side I/Os. The latch 425 remains in the disengaged position.

FIG. 4f shows the cable connector 415 being fully inserted into the assembly such that it is vertically aligned with the side I/Os 420. Here, as with the previous embodiment, grooves are formed in the surface of the interposer near the side I/Os 420 that the bottom springs fit into thereby stopping the forward motion of the cable connector 415 and aligning it with the side I/Os. Upward force exerted by the lower springs 427 keep the bottom of the cable connector 415 raised above the side I/Os 420. The latch 425 remains in the disengaged position.

FIG. 4g shows the assembly after the latch 425 has been pushed forward causing it to press into the upper springs 428. The upper springs lower and compress in response to their being pressed into by the latch 425 which moves the cable connector 415 downward onto the side I/Os causing the cable connector 415 to mate with the side I/Os in a compression mounted manner.

FIG. 4h shows an embodiment of the cable, cable connector and integrated latch 425. Here, note that the latch 425 includes slide holes 441 through which standoffs 442 are located to allow forward and backward motion of the latch 425 relative to the cable connector 415.

FIG. 4i shows an embodiment of the retention bracket 431. The opening 442 formed by the retention bracket 431 that the cable and its connector are inserted into can be partitioned to allow for a pair of cables and brackets (left and right) as discussed in the prior embodiment (e.g., in reference to FIG. 3e).

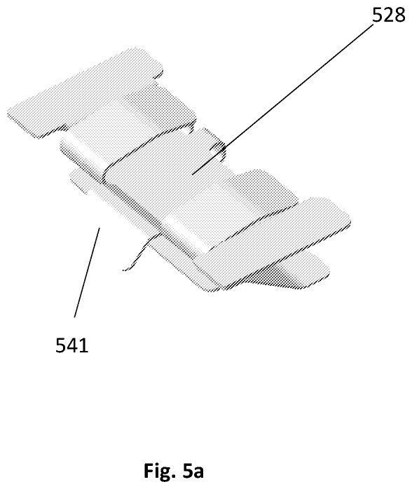

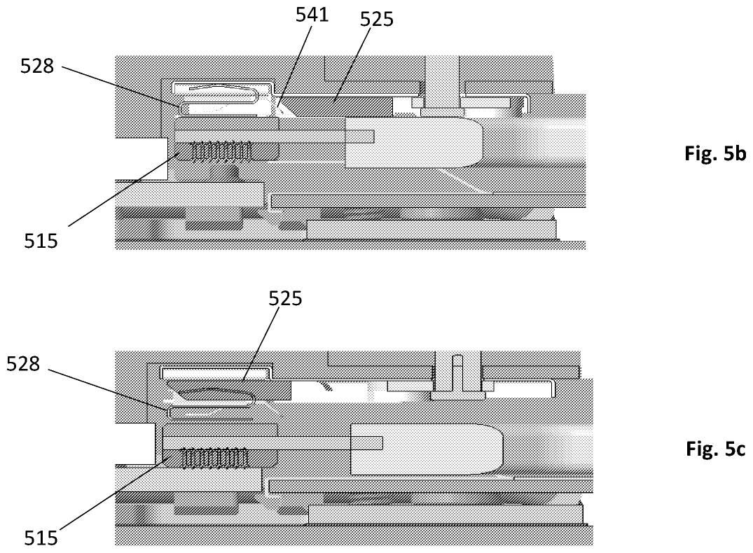

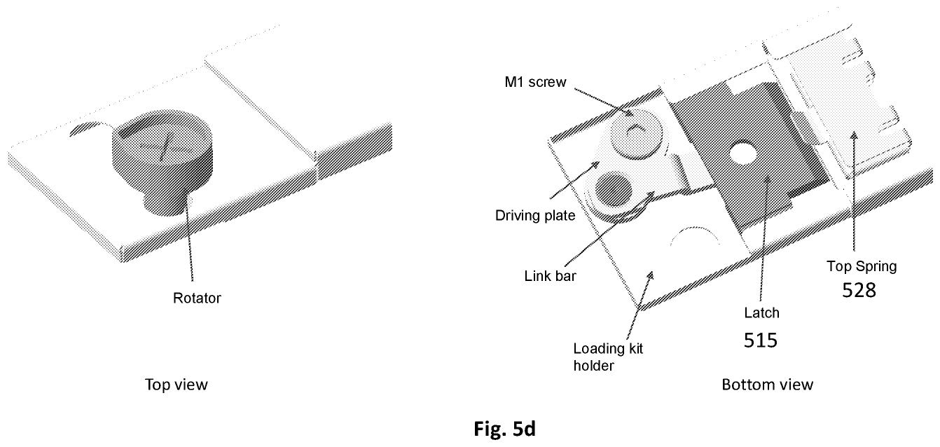

FIGS. 5a, 5, 5c and 5d pertain to yet another embodiment in which the top spring 528 is mechanically integrated into the cooling assembly rather than being attached to the cable connector. FIG. 5a shows a top view of the top spring 518. Notably the top spring includes a forefinger 541 to engage with the latch.

FIGS. 5b and 5c depict latch 525 engagement to the top spring 528 and the resulting vertical movement of the cable connector onto the side I/Os. Specifically, FIG. 5b shows the latch 525 just prior to its contact with the forefinger 541. FIG. 5c shows the latch after it is fully engaged with the forefinger 541 and spring 528 and driven the top spring 528 vertically downward. Although the outline of the top spring 528 in FIG. 5c depicts the top spring being uncompressed, in reality the top spring 528 is would be compressed between the latch 525 and the side I/Os.

FIG. 5d shows a loading unit that is attached, e.g., to the bottom of the heat sink base or chip carrier. As can be seen in the bottom view, not only the latch 515 but also the top spring 528 are housed by the loading unit (as such, a top spring need not be integrated to the cable connector). A rotator is turned by a user to drive the latch forward into the top spring to drive the cable connector lower and make contact to the side I/Os. When turned in the opposite direction, the latch retreats to a disengaged position and the spring expands into the loading unit housing.

It is pertinent to point out that the above embodiments are just a few of a multitude of possible embodiments for connecting to the side I/Os. For example, other mechanical solutions can exist where a spring on a side or bottom of the cable connector and/or near the side I/Os is compressed during installation to cause the electrical/mechanical connection between the side I/Os and cable connector.

Here, with respect to the spring that is compressed to cause the electrical/mechanical compression mount, such a spring need not be an elbow spring or a torsion wire spring but can include other kinds of springs (e.g., a leaf spring) or can be any material that can be compressed or bent but has enough thickness and/or hardness to exert resistance against the compression or bending and return to its original shape when the compressive/bending force is removed. Likewise, the latch need not push in a direction toward the chip package to exert the compression/bending but can push in other directions (for example, the latch is formed as a movable ceiling that is lowered to compress the spring). Thus, the teachings herein are not limited to the specific embodiments described in detail herein.

With respect to the signal wires that are on the cable, generally, any signals can be transported on the cable so long as the cable has appropriate characteristic impedance characteristics for the frequencies of the signals being transported on the cable. In the case of signals having higher frequencies (such as memory signals or high speed peripheral (e.g., PCIe) signals), the cable should have more tightly controlled/specified characteristic impedance tolerances.

The tolerances of the characteristic impedance values of the cable's signal wires can be more forgiving the lower the frequencies (the slower the signals) that are transported by the cable. For example, signals for slower speed peripherals (e.g., mouse, keyboard, display) can be carried by the cable where characteristic impedance is less emphasized in the design of the cable whereas the cable should have dielectric and conductive structures with specific dimensions and of specific materials to effect a specific characteristic impedance for higher speed signals (e.g., high speed memory (e.g., JEDEC DDR) and/or high speed peripheral (PCIe) signals).

In various embodiments the cable is a “phonics” cable composed of fiber optic cable and optical to electrical and/or electrical to optical converters at the ends of the fiber optic cable.

It is also pertinent to point out that although embodiments above have depicted side connection at only one side of a chip package, other embodiments can extend the teachings above to include side connections at more than one side of a semiconductor chip package (e.g., two, three or four sides).

In various embodiments, the heat sink is replaced with a cold plate or vapor chamber for liquid cooling. In the case of a cold plate, cooled fluid is routed through the cold plate to absorb and remove heat generated by the semiconductor chip(s) in the chip package 102. In the case of a vapor chamber, liquid within the vapor chamber absorbs heat generated by the semiconductor chip(s) in the chip package which, in turn, causes vaporization of the liquid. The vapor is then condensed back to liquid to remove the heat generated by the semiconductor chip(s).

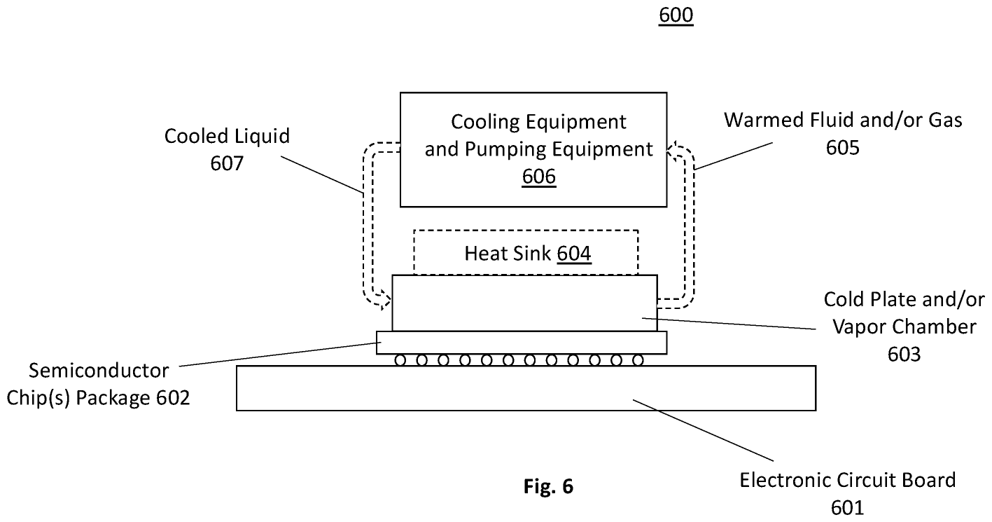

As such, the teachings above can be applied to the cooling apparatus 600 of FIG. 6. FIG. 6 depicts a general liquid cooling apparatus 600 whose features can be found in many different kinds of semiconductor chip cooling systems. As observed in FIG. 6, one or more semiconductor chips within a package 602 are mounted to an electronic circuit board 601. A cold plate 603 is thermally coupled with the package 602 so that the cold plate 603 receives heat generated by the one or more semiconductor chips.

Liquid coolant is within the cold plate 603. If the system also employs air cooling (optional), a heat sink 604 can be thermally coupled to the cold plate 603. Warmed liquid coolant and/or vapor 605 leaves the cold plate 603 to be cooled by one or more items of cooling equipment (e.g., heat exchanger(s), radiator(s), condenser(s), refrigeration unit(s), etc.) and pumped by one or more items of pumping equipment (e.g., dynamic (e.g., centrifugal), positive displacement (e.g., rotary, reciprocating, etc.)) 606. Cooled liquid 607 then enters the cold plate 603 and the process repeats.

With respect to the cooling equipment and pumping equipment 606, cooling activity can precede pumping activity, pumping activity can precede cooling activity, or multiple stages of one or both of pumping and cooling can be intermixed (e.g., in order of flow: a first cooling stage, a first pumping stage, a second cooling stage, a second pumping stage, etc.) and/or other combinations of cooling activity and pumping activity can take place.

Moreover, the intake of any equipment of the cooling equipment and pumping equipment 606 can be supplied by the cold plate of one semiconductor chip package or the respective cold plate(s) of multiple semiconductor chip packages.

In the case of the later (intake received from cold plate(s) of multiple semiconductor chip packages), the semiconductor chip packages can be components on a same electronic circuit board or multiple electronic circuit boards. In the case of the later (multiple electronic circuit boards), the multiple electronic circuit boards can be components of a same electronic system (e.g., different boards in a same server computer) or different electronic systems (e.g., electronic circuit boards from different server computers). In essence, the general depiction of FIG. 6 describes compact cooling systems (e.g., a cooling system contained within a single electronic system), expansive cooling systems (e.g., cooling systems that cool the components of any of a rack, multiple racks, a data center, etc.) and cooling systems in between.

The above discussion focused on standard liquid cooling with a cold plate. For vapor cooling, the cold plate is replaced with a vapor chamber 603. The vapor chamber can emit vapor 605 which is condensed to liquid by the cooling equipment 606. Cooled liquid 607 is then pumped back into the vapor chamber 603. In another approach the vapor chamber 603 is sealed and is thermally coupled to a cold plate which operates according to standard liquid cooling as described above.

Any of a heat sink, cold plate, and vapor chamber can be referred to more generally as a cooling mass.

In still other embodiments the cooling assembly and chip package with side I/Os are immersed in a immersion bath of an immersion cooled system. In the case of an immersion cooled system the electronics are immersed in a bath of electrically insulating liquid. Notably, in such immersion cooling implementations (or even air cooled low power semiconductor chip implementations), the integrated heat spreader need not be added. For example, a “packaged chip” corresponds to FIG. 3a but not FIG. 3b (no heat spreader is added). In this case, a heat sink or cold plate may not be present in which case hardware is added to assist the cable connector's connection to the side I/Os (e.g., a socket for the cable connector to plug into is added to the chip package substrate).

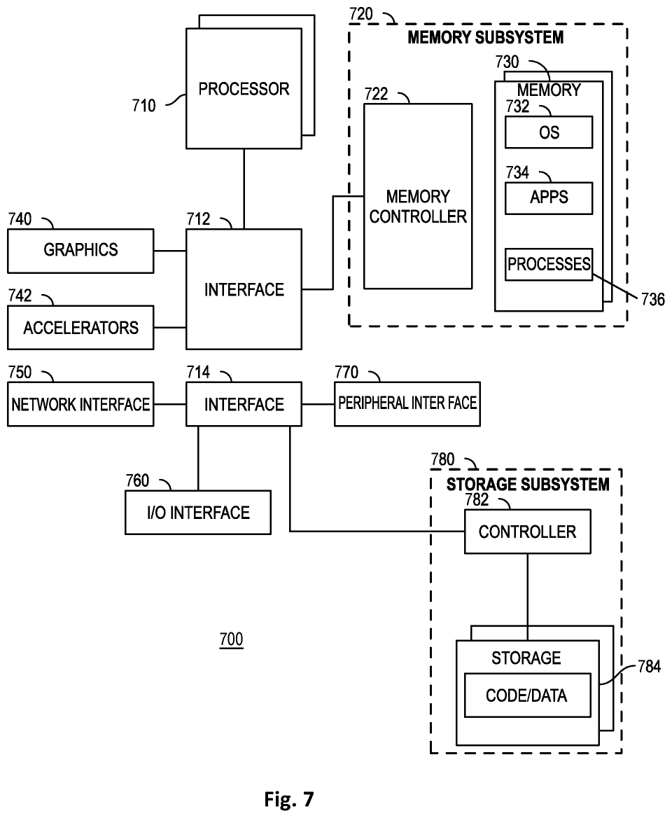

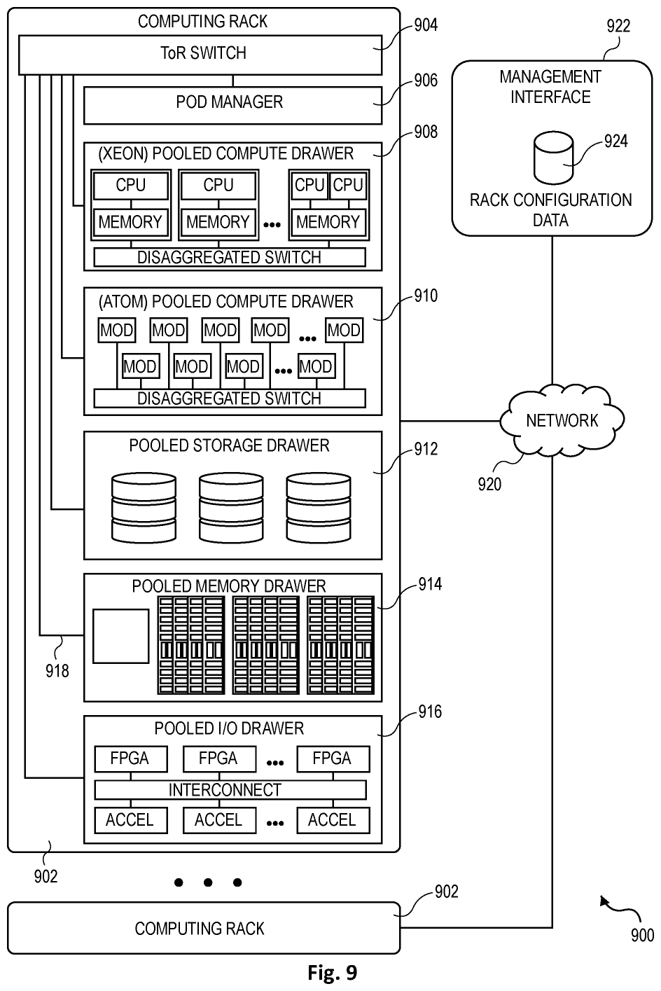

The following discussion concerning FIGS. 7, 8, and 9 are directed to systems, data centers and rack implementations, generally. As such, FIG. 7 generally describes possible features of an electronic system that can include one or more semiconductor chip packages having a cooling assembly that is designed according to the teachings above. FIG. 7 describes possible features of a data center that include such electronic systems. FIG. 9 describes possible features of a rack having one or more such electronic systems installed into it.

FIG. 7 depicts an example system. System 700 includes processor 710, which provides processing, operation management, and execution of instructions for system 700. Processor 710 can include any type of microprocessor, central processing unit (CPU), graphics processing unit (GPU), processing core, or other processing hardware to provide processing for system 700, or a combination of processors. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include one or more network processors to perform such networking functions (e.g., in a pipelined fashion or otherwise).

In one example, system 700 includes interface 712 coupled to processor 710, which can represent a higher speed interface or a high throughput interface for system components that needs higher bandwidth connections, such as memory subsystem 720 or graphics interface components 740, or accelerators 742. Interface 712 represents an interface circuit, which can be a standalone component or integrated onto a processor die. Where present, graphics interface 740 interfaces to graphics components for providing a visual display to a user of system 700. In one example, graphics interface 740 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 740 generates a display based on data stored in memory 730 or based on operations executed by processor 710 or both. In one example, graphics interface 740 generates a display based on data stored in memory 730 or based on operations executed by processor 710 or both.

Accelerators 742 can be a fixed function offload engine that can be accessed or used by a processor 710. For example, an accelerator among accelerators 742 can provide compression (DC) capability, cryptography services such as public key encryption (PKE), cipher, hash/authentication capabilities, decryption, or other capabilities or services. In some embodiments, in addition or alternatively, an accelerator among accelerators 742 provides field select controller capabilities as described herein. In some cases, accelerators 742 can be integrated into a CPU socket (e.g., a connector to a motherboard or circuit board that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic circuitry, and programmable processing elements such as field programmable gate arrays (FPGAs). Accelerators 742 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, volatile memory, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software functionality to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710. In some examples, a system on chip (SOC or SoC) combines into one SoC package one or more of: processors, graphics, memory, memory controller, and Input/Output (I/O) control logic circuitry.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

The memory resources can also be tiered (different access times are attributed to different regions of memory), disaggregated (memory is a separate (e.g., rack pluggable) unit that is accessible to separate (e.g., rack pluggable) CPU units), and/or remote (e.g., memory is accessible over a network).

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (ISCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 700 includes interface 714, which can be coupled to interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can transmit data to a remote device, which can include sending data stored in memory. Network interface 750 can receive data from a remote device, which can include storing received data into memory. Various embodiments can be used in connection with network interface 750, processor 710, and memory subsystem 720.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data in a persistent state (e.g., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 714 or processor 710 or can include circuits in both processor 710 and interface 714.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 700. More specifically, power source typically interfaces to one or multiple power supplies in system 700 to provide power to the components of system 700. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 700 can be implemented as a disaggregated computing system. For example, the system 700 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Although a computer is largely described by the above discussion of FIG. 7, other types of systems to which the above described invention can be applied and are also partially or wholly described by FIG. 7 are communication systems such as routers, switches and base stations.

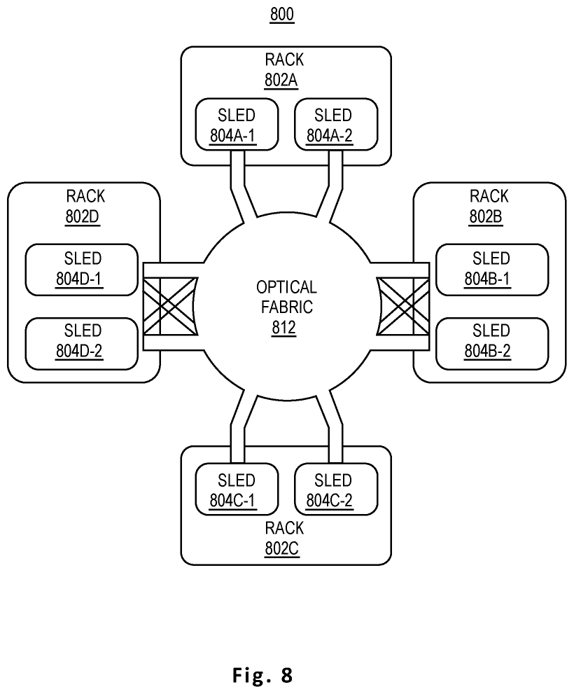

FIG. 8 depicts an example of a data center. Various embodiments can be used in or with the data center of FIG. 8. As shown in FIG. 8, data center 800 may include an optical fabric 812. Optical fabric 812 may generally include a combination of optical signaling media (such as optical cabling) and optical switching infrastructure via which any particular sled in data center 800 can send signals to (and receive signals from) the other sleds in data center 800. However, optical, wireless, and/or electrical signals can be transmitted using fabric 812. The signaling connectivity that optical fabric 812 provides to any given sled may include connectivity both to other sleds in a same rack and sleds in other racks.

Data center 800 includes four racks 802A to 802D and racks 802A to 802D house respective pairs of sleds 804A-1 and 804A-2, 804B-1 and 804B-2, 804C-1 and 804C-2, and 804D-1 and 804D-2. Thus, in this example, data center 800 includes a total of eight sleds.

Optical fabric 812 can provide sled signaling connectivity with one or more of the seven other sleds. For example, via optical fabric 812, sled 804A-1 in rack 802A may possess signaling connectivity with sled 804A-2 in rack 802A, as well as the six other sleds 804B-1, 804B-2, 804C-1, 804C-2, 804D-1, and 804D-2 that are distributed among the other racks 802B, 802C, and 802D of data center 800. The embodiments are not limited to this example. For example, fabric 812 can provide optical and/or electrical signaling.

FIG. 9 depicts an environment 900 that includes multiple computing racks 902, each including a Top of Rack (ToR) switch 904, a pod manager 906, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 908, and INTEL® ATOM™ pooled compute drawer 910, a pooled storage drawer 912, a pooled memory drawer 914, and a pooled I/O drawer 916. Each of the pooled system drawers is connected to TOR switch 904 via a high-speed link 918, such as a 40 Gigabit/second (Gb/s) or 100 Gb/s Ethernet link or a 100+ Gb/s Silicon Photonics (SiPh) optical link. In one embodiment high-speed link 918 comprises a 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 900 may be interconnected via their TOR switches 904 (e.g., to a pod-level switch or data center switch), as illustrated by connections to a network 920. In some embodiments, groups of computing racks 902 are managed as separate pods via pod manager(s) 906. In one embodiment, a single pod manager is used to manage all of the racks in the pod. Alternatively, distributed pod managers may be used for pod management operations. Rack environment 900 further includes a management interface 922 that is used to manage various aspects of the Rack environment. This includes managing rack configuration, with corresponding parameters stored as rack configuration data 924.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store program code. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the program code implements various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled, and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1.-20. (canceled)

21. An apparatus, comprising:
a semiconductor chip package, the semiconductor chip package comprising a substrate, the substrate comprising side I/Os, the side I/Os coupled to I/Os of a semiconductor chip within the semiconductor chip package.

22. The apparatus of claim 21 wherein the side I/Os and an integrated heat spreader are on a same side of the substrate.

23. The apparatus claim 21 further comprising a cooling assembly that is mechanically integrated with the semiconductor chip package, the cooling assembly comprising a passageway located between a base of a cooling mass and a bolster plate, the passageway to guide a cable connector to the side I/Os.

24. The apparatus of claim 23 wherein a spring that is mechanically coupled to the cable connector is to be compressed when the cable connector is mated with the side I/Os.

25. The apparatus of claim 24 further comprising a latch, the spring to be between the latch and the cable connector when the cable connector is mated to the side I/Os.

26. An apparatus, comprising:
at least a portion of a cooling assembly that is to be mechanically integrated with a semiconductor chip package, the at least a portion of the cooling assembly comprising a passageway that is to be located between a base of a cooling mass of the cooling assembly and a bolster plate of the cooling assembly, the passageway to guide a cable connector to side I/Os, the side I/Os to couple to first I/Os of a semiconductor chip within the semiconductor chip package, the side I/Os to be located between the base of the cooling mass and an electronic circuit board that is to be between the bolster plate and a back plate and is to couple to second I/Os of the semiconductor chip through a socket that the semiconductor chip package is to be plugged into.

27. The apparatus of claim 26 further comprising a spring that is to be mechanically coupled to the cable connector and that is to be compressed when the cable connector is connected to the side I/Os.

28. The apparatus of claim 27 the at least a portion of the cooling assembly further comprises a latch, the spring to be between the latch and the cable connector when the cable connector is connected to the side I/Os.

29. The apparatus of claim 28 wherein a chip package carrier of the cooling assembly further comprises a groove to guide movement of the latch.

30. The apparatus of claim 26 wherein the passageway is formed in a chip package carrier of the cooling assembly.

31. The apparatus of claim 26 wherein the at least a portion of the cooling assembly further comprises a latch, the latch to vertically move the cable connector into electro-mechanical contact with the side I/Os.

32. The apparatus of claim 31 wherein the latch has first and second arms, the first arm to engage with a first spring on the cable connector, the second arm to engage with a second spring on the cable connector, the cable connector's I/Os located between the first and second springs, the first and second springs to be compressed with the vertical movement of the cable connector.

33. The apparatus of claim 26 wherein the semiconductor chip package is to have an integrated heat spreader mounted to a substrate, the substrate having additional surface area that extends beyond a footprint of the integrated heat spreader, the side I/Os residing on the additional surface area of the substrate.

34. The apparatus of claim 26 wherein the socket is mounted to an interposer that is mounted to the electronic circuit board and the side I/Os are on the interposer.

35. The apparatus of claim 26 further comprising a groove next to the side I/Os into which a spring that is attached to the cable connector is to slide into.

36. A data center, comprising:
a plurality of racks, the plurality of racks comprising electronic systems communicatively coupled through one or more networks, at least one of the electronic systems comprising a semiconductor chip package and a cooling assembly that is mechanically integrated with the semiconductor chip package, the cooling assembly comprising a cooling mass, a bolster plate and a back plate, an electronic circuit board located between the bolster plate and the back plate, the cooling assembly comprising a passageway located between a base of the cooling mass and the bolster plate, a cable within the passageway, a connector of the cable mated to side I/Os, the side I/Os coupled to first I/Os of a semiconductor chip within the semiconductor chip package, the side I/Os located between the base of the cooling mass and the electronic circuit board, the electronic circuit board coupled to second I/Os of the semiconductor chip through a socket that the semiconductor chip package is plugged into.

37. The apparatus of claim 36 further comprising a spring that is mechanically coupled to the cable connector, the spring being compressed, the cable connector connected to the side I/Os.

38. The apparatus of claim 37 wherein the cooling assembly further comprises a latch, the spring located between the latch and the cable connector.

39. The apparatus of claim 38 wherein a chip package carrier of the cooling assembly further comprises a groove to guide movement of the latch.

40. The apparatus of claim 36 wherein the passageway is formed in a chip package carrier of the cooling assembly.
